(19) United States
(12) Patent Application Publication
(10) Pub. No.: US 2026/0319191 A1
(43) Pub. Date: Oct. 15, 2026

(54) WIRING SUBSTRATE

(71) Applicant: IBIDEN CO., LTD., Gifu (JP)

(72) Inventors: Kohei KAWAI, Gifu (JP); Haruka FURUMACHI, Gifu (JP)

(73) Assignee: IBIDEN CO., LTD., Gifu (JP)

(21) Appl. No.: 19/692,171

(22) Filed: May 29, 2026

Related U.S. Application Data
(63) Continuation of application No. PCT/JP2024/043794, filed on Dec. 11, 2024.

(30) Foreign Application Priority Data
Dec. 15, 2023 (JP) 2023-211970

(51) Int. Cl. G02B 6/42; G02B 6/43

(52) U.S. Cl. CPC G02B 6/4202; G02B 6/43; G02B 6/4238

(57) ABSTRACT

A wiring substrate includes a substrate having an optical element region and including a conductor layer formed in the optical element region, optical waveguides formed on the substrate such that each of the optical waveguides includes a lower cladding, a core and an upper cladding, and an electrical connection member that is formed in the optical element region of the substrate and electrically connects the conductor layer and an optical element in the optical element region of the substrate. The optical waveguides are formed on the substrate such that the core of each of the optical waveguides is exposed in the optical element region of the substrate and optically couples with the optical element.

### CROSS-REFERENCE TO RELATED APPLICATIONS

The present application is a continuation of and claims the benefit of priority to International Application No. PCT/JP 2024/043794, filed Dec. 11, 2024, which is based upon and claims the benefit of priority to Japanese Application No. 2023-211970, filed Dec. 15, 2023. The entire contents of these applications are incorporated herein by reference.

### FIELD OF THE INVENTION

The present invention relates to a wiring substrate.

### DESCRIPTION OF BACKGROUND ART

Japanese Patent Application Laid-Open Publication No. 2003-215371 describes an optical module in which an optical waveguide is formed on a substrate. The entire contents of this publication are incorporated herein by reference.

### SUMMARY OF THE INVENTION

According to one aspect of the present invention, a wiring substrate includes a substrate having an optical element region and including a conductor layer formed in the optical element region, optical waveguides formed on the substrate such that each of the optical waveguides includes a lower cladding, a core and an upper cladding, and an electrical connection member that is formed in the optical element region and electrically connects the conductor layer and an optical element in the optical element region of the substrate. The optical waveguides are formed on the substrate such that the core of each of the optical waveguides is exposed in the optical element region of the substrate and

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a wiring substrate in which optical waveguides are formed in two directions;

FIG. 1B is a plan view of the wiring substrate in which the optical waveguides are formed in two directions;

FIG. 2 is a plan view of a wiring substrate in which optical waveguides are formed in three directions;

FIG. 3 is a plan view of a wiring substrate in which optical waveguides are formed in four directions;

FIG. 4A is a cross-sectional view of a wiring substrate in which optical waveguides are formed in two directions and a chip is positioned;

FIG. 4B is a plan view of the wiring substrate in which the optical waveguides are formed in two directions and the chip is positioned;

FIG. 4C is a plan view of a wiring substrate in which optical waveguides are formed in three directions and a chip is positioned;

FIG. 4D is a plan view of a wiring substrate in which optical waveguides are formed in four directions and a chip is positioned;

FIG. 4E is a plan view of a wiring substrate in which optical waveguides are formed in two directions and in two rows and a chip is positioned;

FIG. 4F is a plan view of a wiring substrate in which optical waveguides are formed in three directions and in two rows and a chip is positioned;

FIG. 4G is a plan view of a wiring substrate in which optical waveguides are formed in four directions and in two rows and a chip is positioned;

FIG. 4H is a plan view of a wiring substrate in which optical waveguides are formed in two directions and in three rows and a chip is positioned;

FIG. 4I is a plan view of a wiring substrate in which optical waveguides are formed in three directions and in three rows and a chip is positioned;

FIG. 4J is a plan view of a wiring substrate in which optical waveguides are formed in four directions and in three rows and a chip is positioned;

FIG. 5A illustrates a process of preparing a substrate;

FIG. 5B illustrates a process of forming a lower cladding;

FIG. 5C illustrates a process of forming a core;

FIG. 5D illustrates a process of forming an upper cladding;

FIG. 5E illustrates a process of mounting an optical element;

FIG. 6 illustrates a wiring substrate of a first connection form;

FIG. 7 illustrates a wiring substrate of a second connection form;

FIG. 8 illustrates a wiring substrate of a third connection form;

FIG. 9 illustrates a wiring substrate of a fourth connection form;

FIG. 10 illustrates an adiabatic coupling;

FIG. 11 is a cross-sectional view for describing a build-up substrate;

FIG. 12 is a cross-sectional view illustrating a structure of a build-up substrate;

FIG. 13 is a plan view illustrating an optical waveguide of a first example;

FIG. 14 is a plan view illustrating an optical waveguide of a second example; and

FIG. 15 illustrates roles of components in the wiring substrate.

### DETAILED DESCRIPTION OF THE EMBODIMENTS

Embodiments will now be described with reference to the accompanying drawings, wherein like reference numerals designate corresponding or identical elements throughout the various drawings.

A wiring substrate 10 is a substrate for inputting and outputting optical signals and electrical signals. Multiple optical waveguides 40 can be formed in the wiring substrate 10. In the following, three types are described regarding directions in which the optical waveguides 40 are formed.

### Two Directions

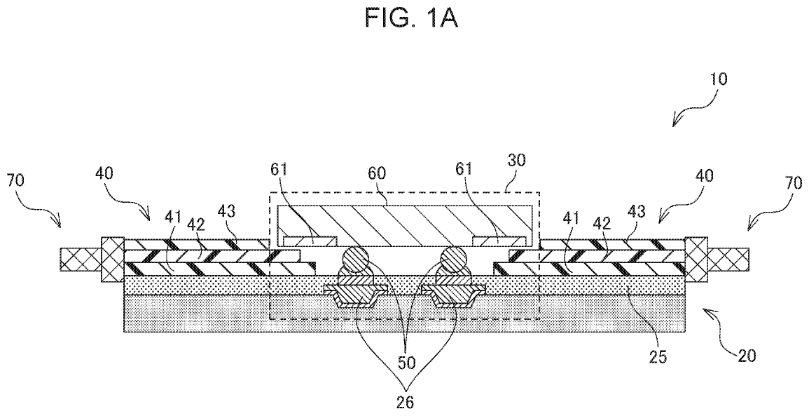

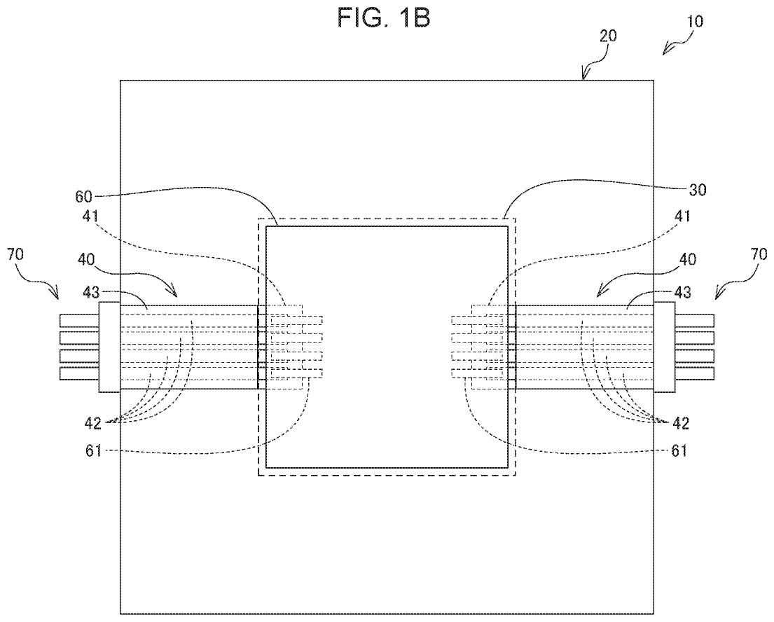

FIG. 1A is a cross-sectional view of the wiring substrate 10 in which the optical waveguides 40 are formed in two directions. FIG. 1B is a plan view of the wiring substrate 10 in which the optical waveguides 40 are formed in two directions. The wiring substrate 10 illustrated in FIGS. 1A and 1B corresponds to a first type. The wiring substrate 10 includes a substrate 20 having a conductor layer 26. On the substrate 20, an optical element region 30 and optical waveguides 40 each having a lower cladding 41, a core 42, and an upper cladding 43 are formed. The multiple waveguides may be formed in one direction.

In the optical element region 30, an electrical connection member 50 for electrically connecting the conductor layer 26 and the optical element region 30 is provided. The electrical connection member 50 is a metal body such as a solder bump. In each optical waveguide 40, the core 42 that optically couples with the optical element region 30 is exposed. Multiple optical waveguides 40 are formed. The multiple optical waveguides 40 are formed in different directions with the optical element region 30 as a center. Specifically, two optical waveguides 40 are formed in two directions, on the left side and the right side of the optical element region 30. Further, in FIGS. 1A and 1B, two optical waveguides 40 are formed on the same straight line at positions opposing each other across the optical element region 30; however the two optical waveguides 40 may be formed at different angles at positions opposing each other across the optical element region 30. That is, as illustrated in FIG. 1B, the two optical waveguides 40 are formed so as to intersect perpendicularly with an outer edge of the optical element region 30; however, they may be formed so as to intersect with the outer edge of the optical element region 30 at an angle other than a right angle (an acute angle or an obtuse angle). In this case, the left-side optical waveguide 40 and the right-side optical waveguide 40 can be formed at different angles. Further, the two optical waveguides 40 may be formed not on the same straight line at two positions across the optical element region 30, but may be formed in an L-shape or in a V-shape. Further, the two optical waveguides 40 may be formed not on the same straight line in the left-right direction as illustrated in FIG. 1B at two positions across the optical element region 30, but on the same straight line in the up-down direction as illustrated in FIG. 1B. In other words, the optical waveguides 40 may be formed symmetrically in the left-right direction or in the up-down direction with respect to the optical element region 30.

In the optical element region 30, one optical element 60 is positioned. The optical element 60 performs input and output of optical signals and conversion between electrical signals and optical signals. An exposed portion of the core 42 and a terminal 61 of the optical element 60 are optically coupled. In the optical element region 30, one optical element 60 can be coupled to multiple optical waveguides 40. In the optical element region 30, multiple units each formed by coupling one optical element and one optical waveguide 40 can be formed in one direction.

An end portion of the upper cladding 43 of each optical waveguide 40 serves as a boundary with the optical element region 30. At one end of each optical waveguide 40 (an inner end portion in FIG. 1A), the optical element region 30 can be formed. At the other end of each optical waveguide 40 (an outer end portion in FIG. 1A), an external connection member 70 (for example, an optical fiber, an optical element, or the like) can be positioned.

### Three Directions

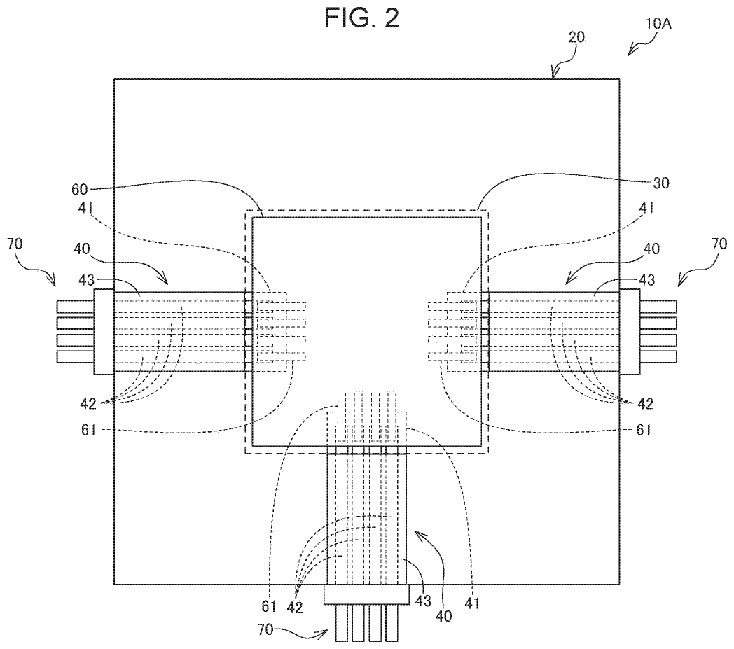

FIG. 2 is a plan view of a wiring substrate (10A) in which the optical waveguides 40 are formed in three directions. The wiring substrate (10A) illustrated in FIG. 2 corresponds to a second type. The multiple optical waveguides 40 are formed in different directions with the optical element region 30 as a center. Specifically, three optical waveguides 40 are formed in three directions: on the left side, the right side, and the lower side of the optical element region 30. Other structural elements are the same as those in FIGS. 1A and 1B. The multiple waveguides may be formed in one direction. The three optical waveguides 40 are formed in a T-shape; however, they may be formed in a Y-shape. The three optical waveguides 40 may all be formed straight along the up-down direction or the left-right direction. The three optical waveguides 40 may all be formed inclined with respect to the up-down direction or the left-right direction. Some of the three optical waveguides 40 may be formed straight along the up-down direction or the left-right direction, and the remaining waveguides may be formed inclined with respect to the up-down direction or the left-right direction.

### Four Directions

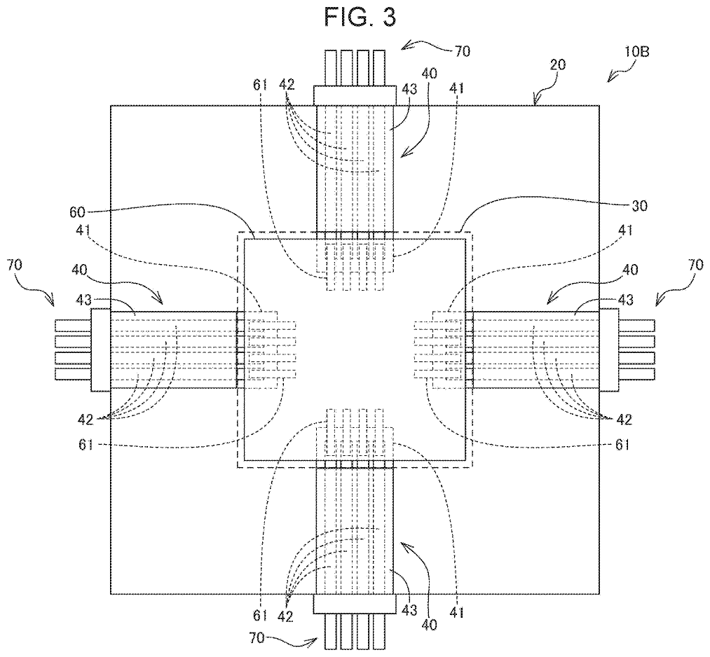

FIG. 3 is a plan view of a wiring substrate (10B) in which the optical waveguides 40 are formed in four directions. The wiring substrate (10B) illustrated in FIG. 3 corresponds to a third type. The multiple optical waveguides 40 are formed in different directions with the optical element region 30 as a center. Specifically, four optical waveguides 40 are formed in four directions: on the left side, the right side, the upper side, and the lower side of the optical element region 30. Other structural elements are the same as those in FIGS. 1A and 1B. The multiple waveguides may be formed in one direction. The four optical waveguides 40 are formed in a cross shape; however, they may be formed in an X-shape. The four optical waveguides 40 may all be formed straight along the up-down direction or the left-right direction. The four optical waveguides 40 may all be formed inclined with respect to the up-down direction or the left-right direction. Some of the four optical waveguides 40 may be formed straight along the up-down direction or the left-right direction, and the remaining waveguides may be formed inclined with respect to the up-down direction or the left-right direction.

The optical element region 30 indicates a region in which an optical element 60 can be positioned. An exposed portion of the core 42 of each optical waveguide 40 can serve as a boundary line between the optical element region 30 and other regions. In the optical element region 30, one or multiple optical elements 60 may be positioned, and further, semiconductors or electronic components other than the optical elements 60 may also be positioned. A portion of the optical element region 30 where no optical waveguide 40 is formed can be formed with any size. For example, a portion of the optical element region 30 where no optical waveguide 40 is formed can be determined such that its size is equivalent to a distance between a boundary line of an exposed portion of the core 42 of an optical waveguide 40 and an optical element 60. For example, a length from the outer edge of the optical element region 30 to an optical element 60 can be made equal to a length from an inner end portion of the upper cladding 43 to the optical element 60.

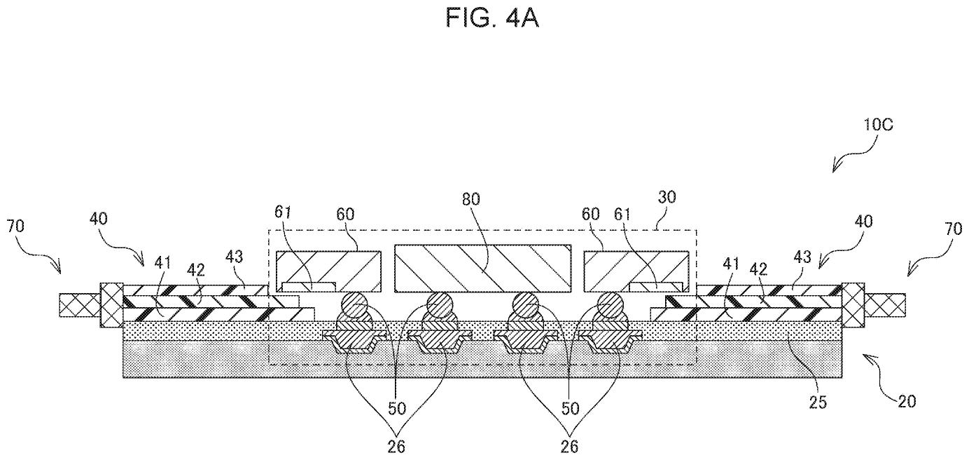

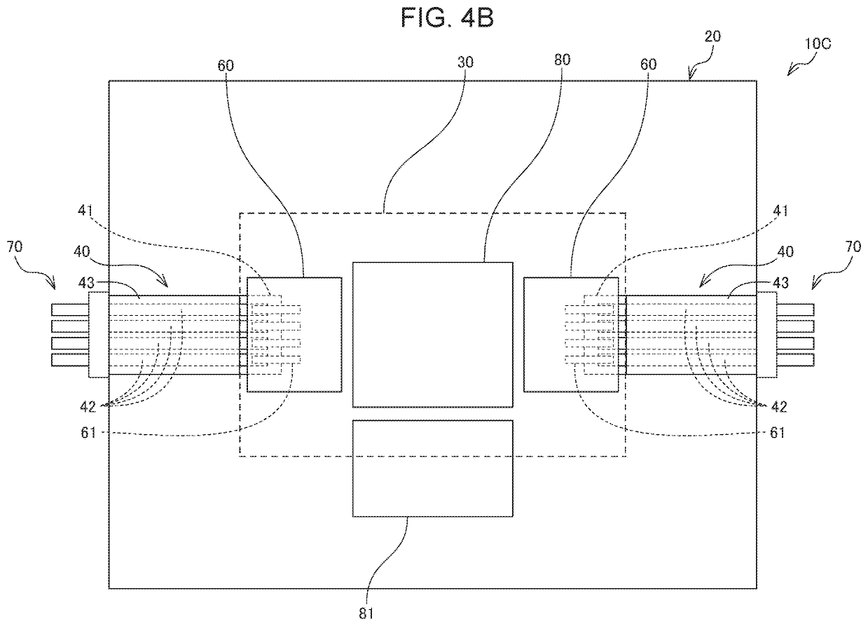

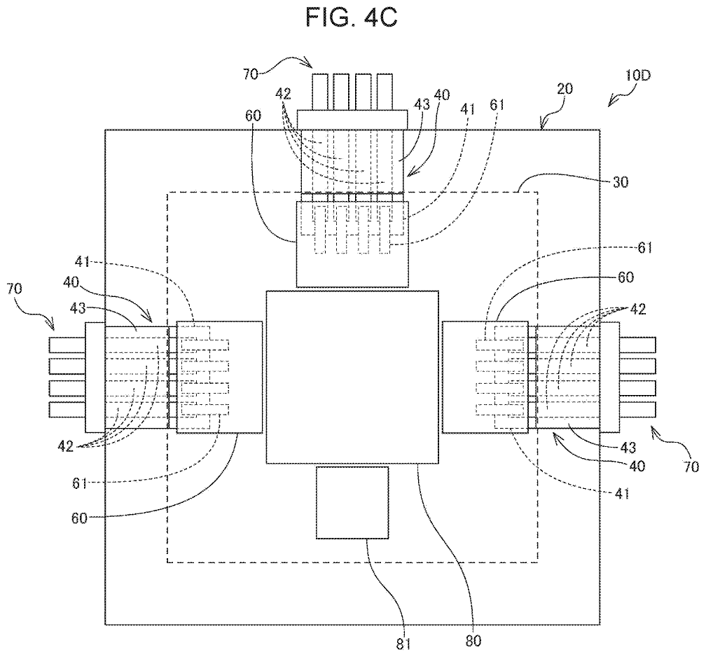

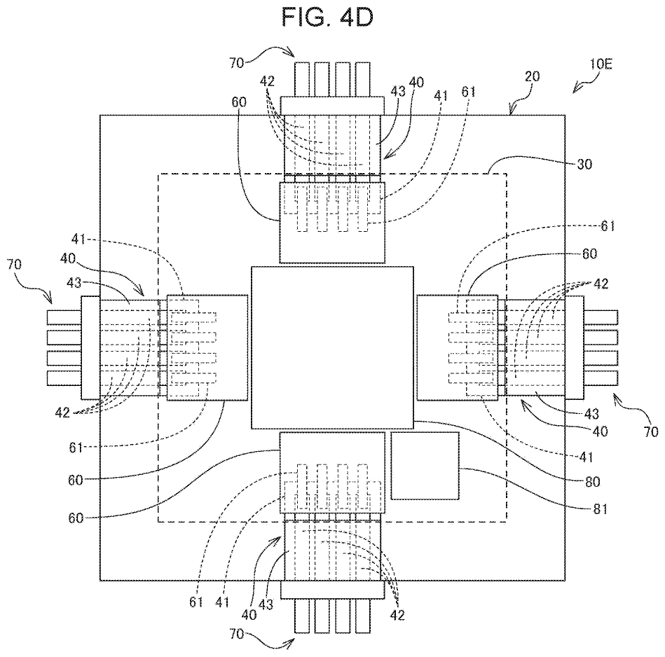

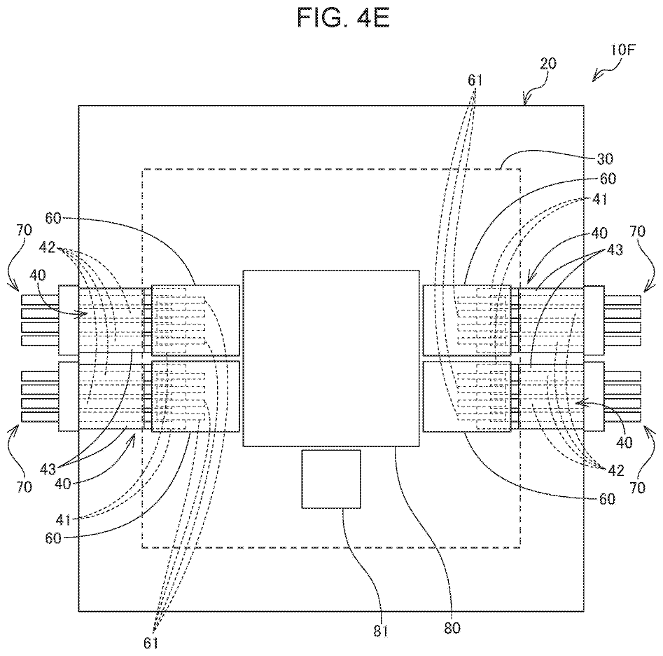

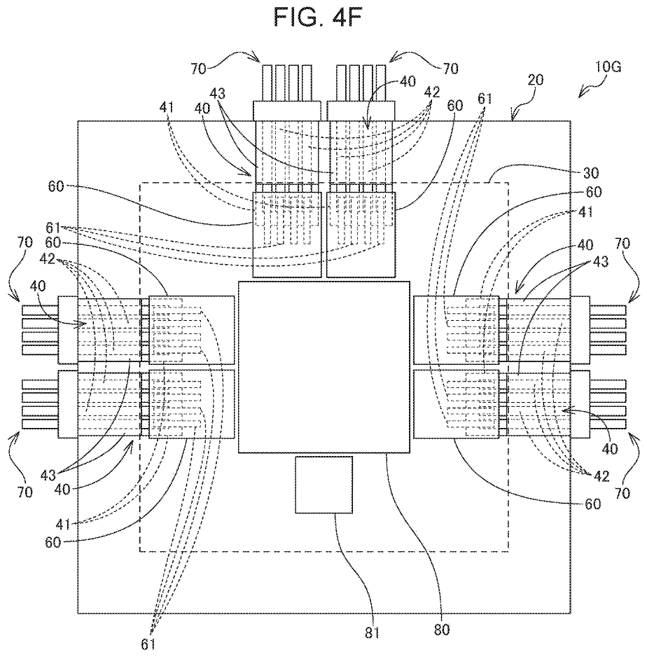

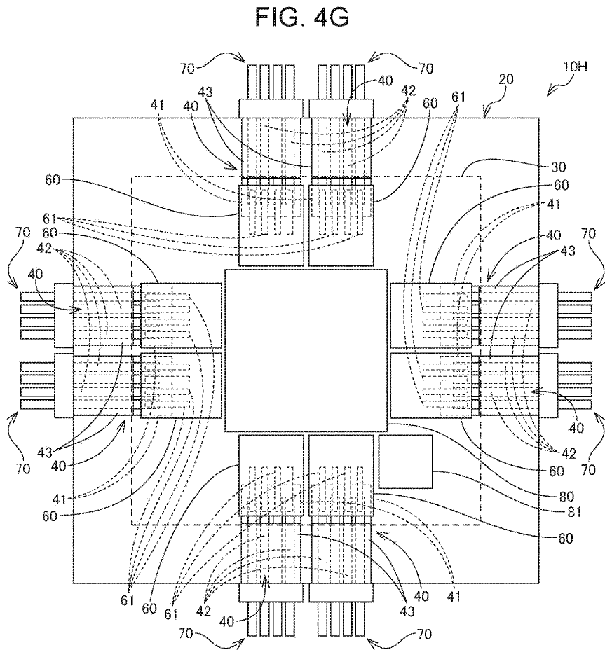

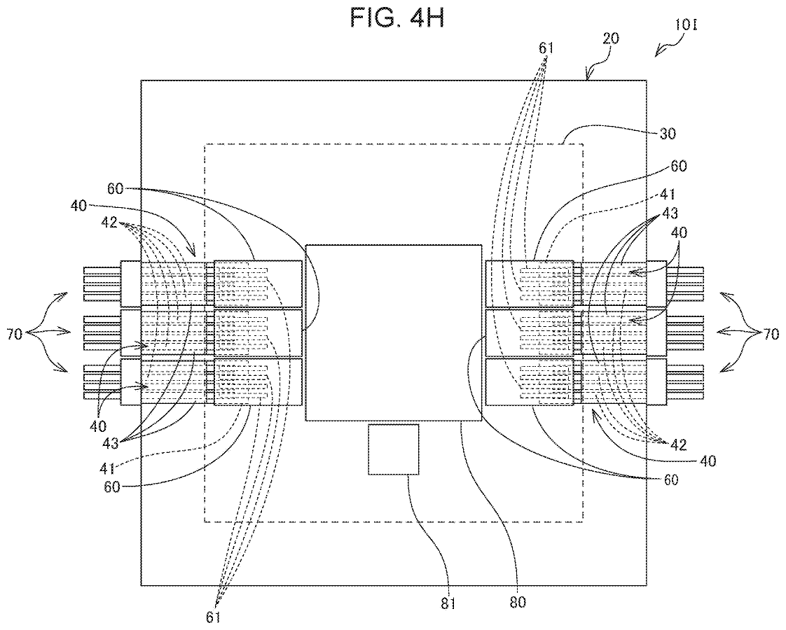

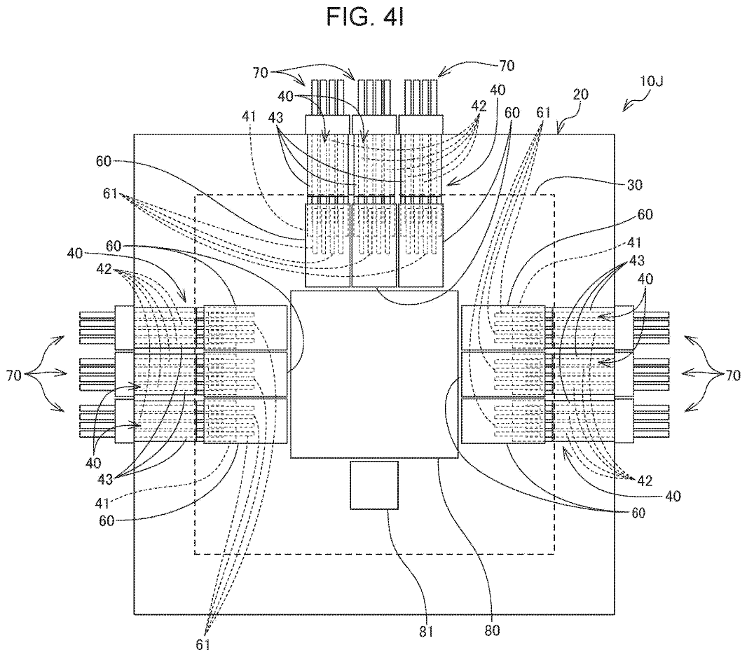

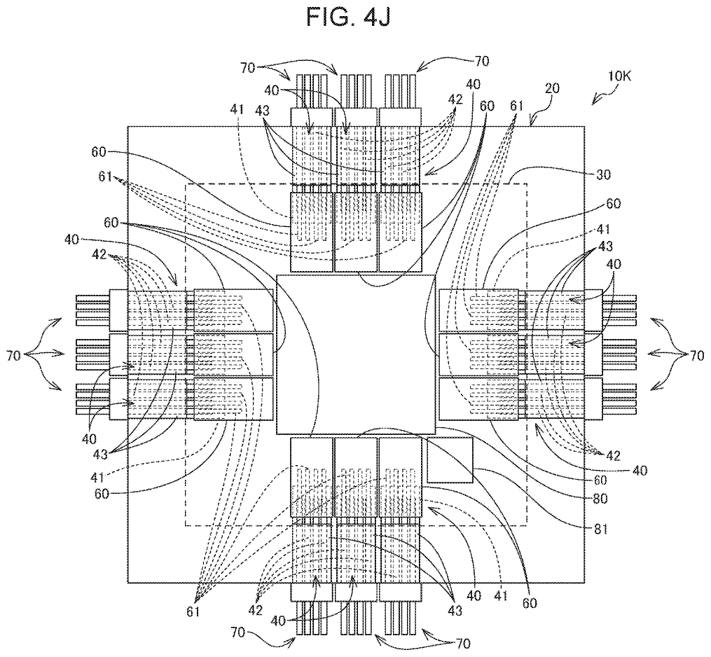

FIG. 4A is a cross-sectional view of a wiring substrate (10C) in which optical waveguides 40 are formed in two directions and a chip 80 is positioned. FIG. 4B is a plan view of the wiring substrate (10C) in which the optical waveguides 40 are formed in two directions and the chip 80 is positioned. The wiring substrate (10C) illustrated in FIGS. 4A and 4B includes the chip 80 that is electrically connected to optical elements 60. The chip 80 may be an electrical circuit or an information processing circuit, or may be any other chip. The chip 80 can input or output electrical signals of the optical elements 60. The chip 80 can convert analog signals to digital signals or, via the conductor layer 26 of the substrate 20, input or output electrical signals (digital signals) to or from other components or external terminals.

As illustrated in FIG. 4B, a chip 81, separate from the chip 80, can be positioned below the chip 80. The chip 81 may have the same function as the chip 80, or may have a different function from the chip 80. The chip 81 may be electrically connected to the chip 80, or may be electrically connected to the optical elements 60. The illustrated positioning of the chip 81 is merely an example, and the chip 81 may be positioned at a location not illustrated (for example, on a substrate separate from the substrate 20).

The size of the chips (80, 81) is preferably larger than the size of the optical elements 60. However, the size of the chips (80, 81) may be smaller than the size of the optical elements 60, or may be the same size. As illustrated in FIG. 4A, the height of the chip 80 is preferably higher than the height of the optical elements 60. However, the height of the chip 80 may be lower than the height of the optical element 60, or may be the same height. This point also applies to the chip 81. As illustrated in FIG. 4B, the size of the chip 80 is preferably larger than the size of the chip 81. However, the size of the chip 80 may be smaller than the size of the chip 81, or may be the same size.

The chip 80 is positioned between two optical elements 60 such that the optical element 60—chip 80—optical element 60 are aligned in a straight line. The chip 81 is not positioned between the two optical elements 60. The chip 80 is entirely positioned within the optical element region 30. The chip 81 is partially positioned within the optical element region 30. The chip 81 may be entirely positioned within the optical element region 30, or may be positioned outside the optical element region 30.

Multiple optical elements 60 are positioned in the optical element region 30. Specifically, two optical elements 60 are positioned in the optical element region 30. The multiple optical waveguides 40 are formed in different directions with the optical element region 30 as a center. Specifically, two optical waveguides 40 are formed in two directions, on the left side and the right side of the optical element region 30. In the optical element region 30, multiple optical waveguides 40 and multiple optical elements 60 are positioned. Three optical waveguides 40 may be formed in three directions as illustrated in FIG. 2, or four optical waveguides 40 may be formed in four directions as illustrated in FIG. 3. Further, for mounting the optical elements 60, the chip 80, and the chip 81, the chip 80 and the chip 81 may be mounted after mounting the optical elements 60, or the optical elements 60 may be mounted after mounting the chip 80 and the chip 81, and the order of mounting the optical elements 60, the chip 80, and the chip 81 is not particularly limited. This point also applies to other wiring substrates.

FIG. 4C is a plan view of a wiring substrate (10D) in which optical waveguides 40 are formed in three directions and a chip 80 is positioned. The wiring substrate (10D) illustrated in FIG. 4C includes the chip 80 that is electrically connected to optical elements 60. A chip 81, separate from the chip 80, can be positioned below the chip 80.

The chips (80, 81) of the wiring substrate (10D) illustrated in FIG. 4C may be the same as the chips (80, 81) of the wiring substrate (10C) illustrated in FIG. 4B, or may be different chips. The chip 80 and the chip 81 are entirely positioned within the optical element region 30. The chip 81 may be partially positioned within the optical element region 30, or may be positioned outside the optical element region 30. The size and height of the chips (80, 81), as well as their positions and the like, may be the same as those in the wiring substrate (10C) illustrated in FIG. 4B, or may be different. The details regarding the chips (80, 81) of the wiring substrate (10D) also apply to a wiring substrate (10E), a wiring substrate (10F), a wiring substrate (10G), a wiring substrate (10H), a wiring substrate (10I), a wiring substrate (10J), and a wiring substrate (10K).

The chip 80 is positioned between the left-side optical element 60 and the right-side optical element 60 such that the left-side optical element 60—chip 80—right-side optical element 60 are aligned in a straight line. The chip 80 is positioned between the upper-side optical element 60 and the chip 81 such that the upper-side optical element 60 chip 80-chip 81 are aligned in a straight line. The chip 81 is not positioned between the left-side optical element 60 and the right-side optical element 60.

Multiple optical elements 60 are positioned in the optical element region 30. Specifically, three optical elements 60 are positioned in the optical element region 30. The multiple optical waveguides 40 are formed in different directions with the optical element region 30 as a center. Specifically, three optical waveguides 40 are formed in three directions, on the left side, the right side, and the upper side of the optical element region 30. In the optical element region 30, multiple optical waveguides 40 and multiple optical elements 60 are positioned.

FIG. 4D is a plan view of the wiring substrate (10E) in which optical waveguides 40 are formed in four directions and a chip 80 is positioned. The wiring substrate (10E) illustrated in FIG. 4C includes the chip 80 that is electrically connected to optical elements 60. A chip 81, separate from the chip 80, can be positioned on the lower right side of the chip 80.

The chip 80 is positioned between the left-side optical element 60 and the right-side optical element 60 such that the left-side optical element 60—chip 80—right-side optical element 60 are aligned in a straight line. The chip 80 is positioned between the upper-side optical element 60 and the lower-side optical element 60 such that the upper-side optical element 60—chip 80—lower-side optical element 60 are aligned in a straight line. The chip 81 is not positioned between the left-side optical element 60 and the right-side optical element 60. The chip 81 is not positioned between the upper-side optical element 60 and the lower-side optical element 60. The chip 81 is positioned at a position where a part thereof overlaps with the chip 80 when viewed in the up-down direction in the drawing. As a result, the chip 80 and the chip 81 can be connected in a straight line in the up-down direction in the drawing. The chip 81 may be positioned at a position where it does not overlap with the chip 80 when viewed in the up-down direction in the drawing.

Multiple optical elements 60 are positioned in the optical element region 30. Specifically, four optical elements 60 are positioned in the optical element region 30. The multiple optical waveguides 40 are formed in different directions with the optical element region 30 as a center. Specifically, four optical waveguides 40 are formed in four directions: on the left side, the right side, the upper side, and the lower side of the optical element region 30. In the optical element region 30, multiple optical waveguides 40 and multiple optical elements 60 are positioned.

FIG. 4E is a plan view of the wiring substrate (10F) in which optical waveguides 40 are formed in two directions and in two rows and a chip 80 is positioned. The two rows of optical waveguides 40 may be formed in parallel, or may not be formed in parallel (hereinafter, the same applies). The wiring substrate (10F) illustrated in FIG. 4E includes the chip 80 that is electrically connected to optical elements 60. A chip 81, separate from the chip 80, can be positioned below the chip 80.

The chip 80 is positioned between the two left-side optical elements 60 and the two right-side optical elements 60 such that the two left-side optical elements 60-chip 80 two right-side optical elements 60 are aligned in a straight line. The chip 81 is not positioned between the two left-side optical elements 60 and the two right-side optical elements 60.

Multiple optical elements 60 are positioned in the optical element region 30. Specifically, four optical elements 60 are positioned in the optical element region 30. The multiple optical waveguides 40 are formed in different directions with the optical element region 30 as a center. Specifically, a total of four optical waveguides 40 are formed in two directions, on the left side and the right side of the optical element region 30, with two in each direction. In the optical element region 30, multiple optical waveguides 40 and multiple optical elements 60 are positioned.

FIG. 4F is a plan view of the wiring substrate (10G) in which optical waveguides 40 are formed in three directions and in two rows and a chip 80 is positioned. The wiring substrate (10G) illustrated in FIG. 4F includes the chip 80 that is electrically connected to optical elements 60. A chip 81, separate from the chip 80, can be positioned below the chip 80.

The chip 80 is positioned between the two left-side optical elements 60 and the two right-side optical elements 60 such that the two left-side optical elements 60—chip 80—two right-side optical elements 60 are aligned in a straight line. The chip 80 is positioned between the two upper-side optical elements 60 and the chip 81 such that the two upper-side optical elements 60—chip 80—chip 81 are aligned in a straight line. The chip 81 is not positioned between the two left-side optical elements 60 and the two right-side optical elements 60.

Multiple optical elements 60 are positioned in the optical element region 30. Specifically, six optical elements 60 are positioned in the optical element region 30. The multiple optical waveguides 40 are formed in different directions with the optical element region 30 as a center. Specifically, a total of six optical waveguides 40 are formed in three directions, on the left side, the right side, and the upper side of the optical element region 30, with two in each direction. In the optical element region 30, multiple optical waveguides 40 and multiple optical elements 60 are positioned.

FIG. 4G is a plan view of the wiring substrate (10H) in which optical waveguides 40 are formed in four directions and in two rows and a chip 80 is positioned. The wiring substrate (10H) illustrated in FIG. 4G includes the chip 80 that is electrically connected to optical elements 60. A chip 81, separate from the chip 80, can be positioned on the lower right side of the chip 80.

The chip 80 is positioned between the two left-side optical elements 60 and the two right-side optical elements 60 such that the two left-side optical elements 60—chip 80—two right-side optical elements 60 are aligned in a straight line. The chip 80 is positioned between the two upper-side optical elements 60 and the two lower-side optical elements 60 such that the two upper-side optical elements 60—chip 80—two lower-side optical elements 60 are aligned in a straight line. The chip 81 is not positioned between the two left-side optical elements 60 and the two right-side optical elements 60. The chip 81 is not positioned between the two upper-side optical elements 60 and the two lower-side optical elements 60. The chip 81 is positioned at a position where a part thereof overlaps with the chip 80 when viewed in the up-down direction in the drawing. As a result, the chip 80 and the chip 81 can be connected in a straight line in the up-down direction in the drawing. The chip 81 may be positioned at a position where it does not overlap with the chip 80 when viewed in the up-down direction in the drawing.

Multiple optical elements 60 are positioned in the optical element region 30. Specifically, eight optical elements 60 are positioned in the optical element region 30. The multiple optical waveguides 40 are formed in different directions with the optical element region 30 as a center. Specifically, a total of eight optical waveguides 40 are formed in four directions, on the left side, the right side, the upper side, and the lower side of the optical element region 30, with two in each direction. In the optical element region 30, multiple optical waveguides 40 and multiple optical elements 60 are positioned.

FIG. 4H is a plan view of the wiring substrate (10I) in which optical waveguides 40 are formed in two directions and in three rows and a chip 80 is positioned. The three rows of optical waveguides 40 may be formed in parallel, or may not be formed in parallel (hereinafter, the same applies). The wiring substrate (10I) illustrated in FIG. 4H includes the chip 80 that is electrically connected to optical elements 60. A chip 81, separate from the chip 80, can be positioned below the chip 80.

The chip 80 is positioned between the three left-side optical elements 60 and the three right-side optical elements 60 such that the three left-side optical elements 60-chip 80-three right-side optical elements 60 are aligned in a straight line. The chip 81 is not positioned between the three left-side optical elements 60 and the three right-side optical elements 60.

Multiple optical elements 60 are positioned in the optical element region 30. Specifically, six optical elements 60 are positioned in the optical element region 30. The multiple optical waveguides 40 are formed in different directions with the optical element region 30 as a center. Specifically, a total of six optical waveguides 40 are formed in two directions, on the left side and the right side of the optical element region 30, with three in each direction. In the optical element region 30, multiple optical waveguides 40 and multiple optical elements 60 are positioned.

FIG. 4I is a plan view of the wiring substrate (10J) in which optical waveguides 40 are formed in three directions and in three rows and a chip 80 is positioned. The wiring substrate (10J) illustrated in FIG. 4I includes the chip 80 that is electrically connected to optical elements 60. A chip 81, separate from the chip 80, can be positioned on the lower right side of the chip 80.

The chip 80 is positioned between the three left-side optical elements 60 and the three right-side optical elements 60 such that the three left-side optical elements 60—chip 80—three right-side optical elements 60 are aligned in a straight line. The chip 80 is positioned between the three upper-side optical elements 60 and the chip 81 such that the three upper-side optical elements 60—chip 80—chip 81 are aligned in a straight line. The chip 81 is not positioned between the three left-side optical elements 60 and the three right-side optical elements 60.

Multiple optical elements 60 are positioned in the optical element region 30. Specifically, nine optical elements 60 are positioned in the optical element region 30. The multiple optical waveguides 40 are formed in different directions with the optical element region 30 as a center. Specifically, a total of nine optical waveguides 40 are formed in three directions, on the left side, the right side, and the upper side of the optical element region 30, with three in each direction. In the optical element region 30, multiple optical waveguides 40 and multiple optical elements 60 are positioned.

FIG. 4J is a plan view of the wiring substrate (10K) in which optical waveguides 40 are formed in four directions and in three rows and a chip 80 is positioned. The wiring substrate (10K) illustrated in FIG. 4J includes the chip 80 that is electrically connected to optical elements 60. A chip 81, separate from the chip 80, can be positioned below the chip 80.

The chip 80 is positioned between the three left-side optical elements 60 and the three right-side optical elements 60 such that the three left-side optical elements 60—chip 80—three right-side optical elements 60 are aligned in a straight line. The chip 80 is positioned between the three upper-side optical elements 60 and the three lower-side optical elements 60 such that the three upper-side optical elements 60—chip 80—three lower-side optical elements 60 are aligned in a straight line. The chip 81 is not positioned between the three left-side optical elements 60 and the three right-side optical elements 60. The chip 81 is not positioned between the three upper-side optical elements 60 and the three lower-side optical elements 60. The chip 81 is positioned at a position where a part thereof overlaps with the chip 80 when viewed in the up-down direction in the drawing. As a result, the chip 80 and the chip 81 can be connected in a straight line in the up-down direction in the drawing. The chip 81 may be positioned at a position where it does not overlap with the chip 80 when viewed in the up-down direction in the drawing.

Multiple optical elements 60 are positioned in the optical element region 30. Specifically, twelve optical elements 60 are positioned in the optical element region 30. The multiple optical waveguides 40 are formed in different directions with the optical element region 30 as a center. Specifically, a total of twelve optical waveguides 40 are formed in four directions, on the left side, the right side, the upper side, and the lower side of the optical element region 30, with three in each direction. In the optical element region 30, multiple optical waveguides 40 and multiple optical elements 60 are positioned.

The number of rows of the optical waveguides 40 has been described using 1 to 3 as examples, but may be 4 or more. The number of rows of the optical waveguides 40 can be varied depending on the direction. For example, the optical waveguides 40 can be formed with one row on the upper side and the left side, and two rows on the lower side and the right side. Further, the optical waveguides 40 can be formed with one row on the upper side and the lower side, and two rows on the left side and the right side. Furthermore, the optical waveguides 40 can be formed with one row on the upper side, two rows on the left side, three rows on the lower side, and four rows on the right side.

The wiring substrate 10 and the like described so far (the wiring substrate 10, the wiring substrate (10A), the wiring substrate (10B), the wiring substrate (10C), the wiring substrate (10D), the wiring substrate (10E), the wiring substrate (10F), the wiring substrate (10G), the wiring substrate (10H), the wiring substrate (10I), the wiring substrate (10J), and the wiring substrate (10K)) can be manufactured by the processes described below.

### Preparing Substrate

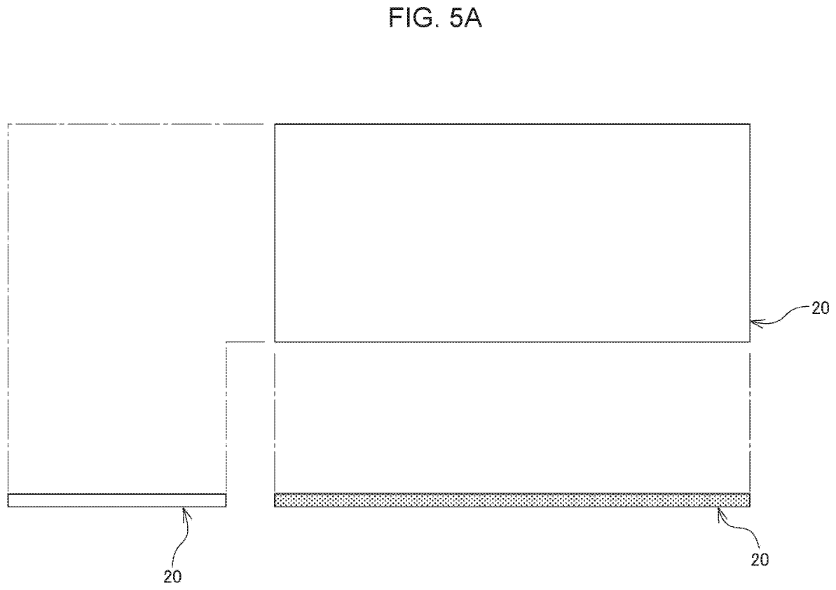

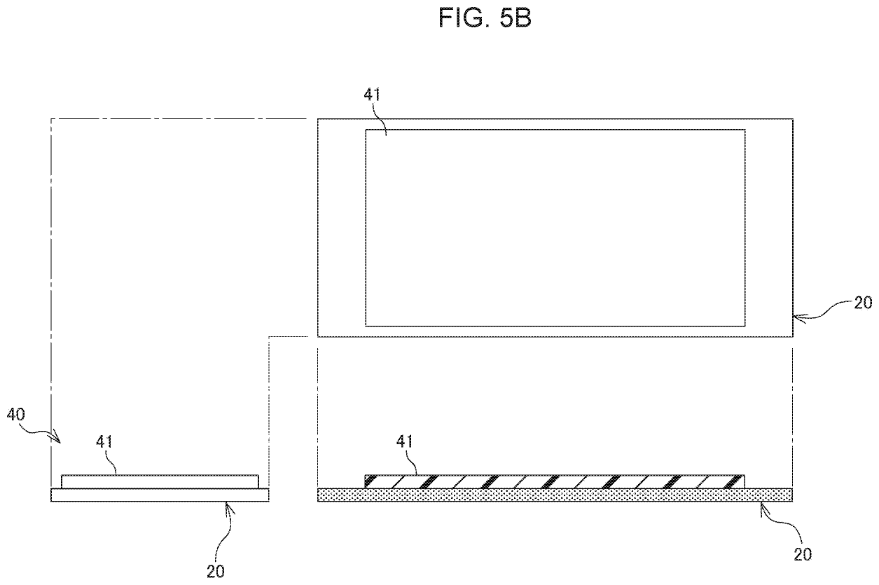

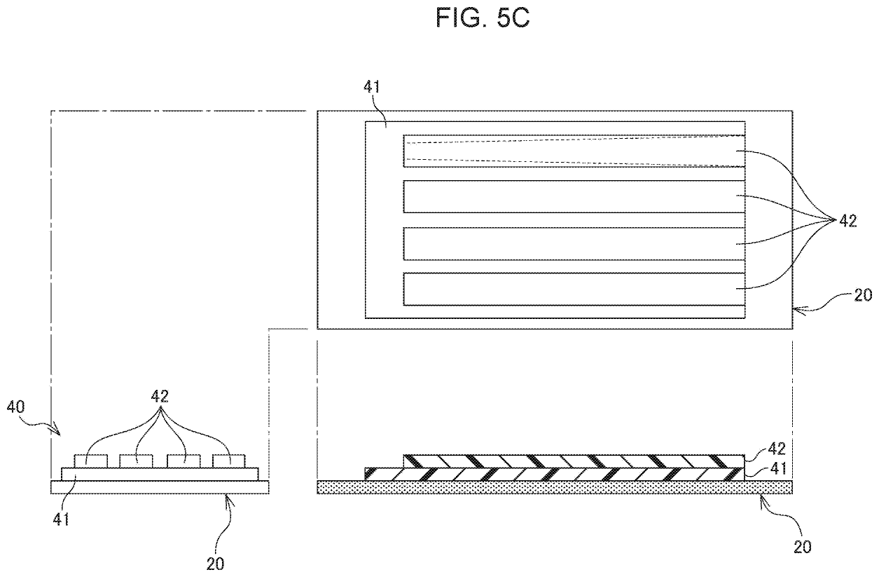

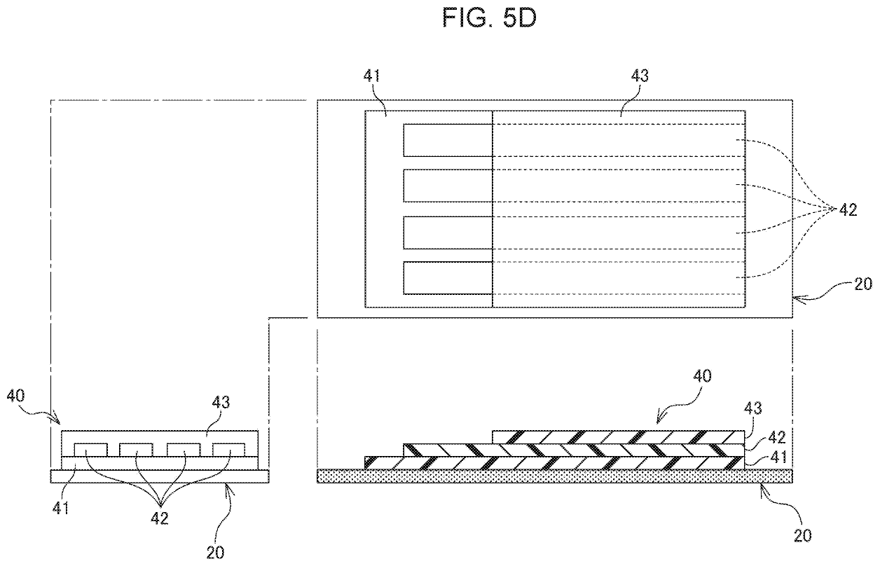

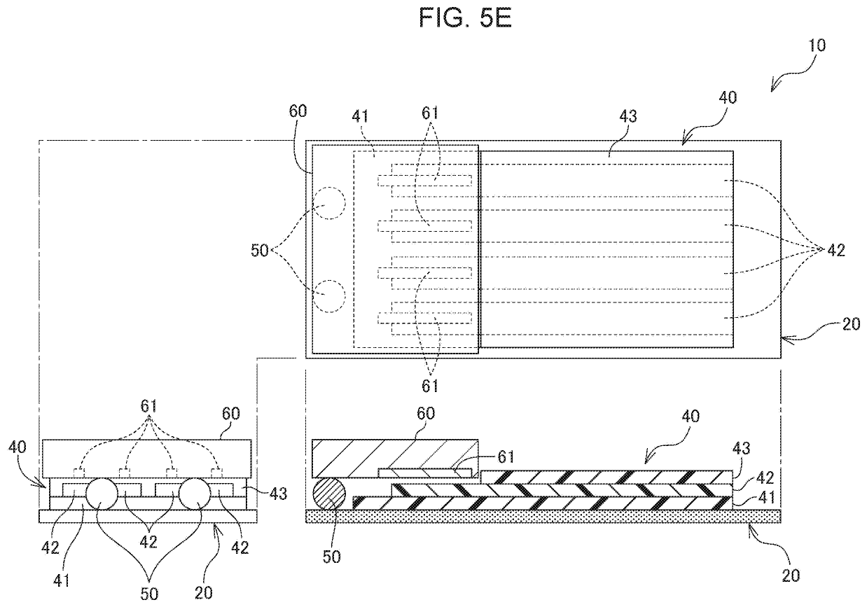

FIG. 5A illustrates a process of preparing the substrate 20. The upper drawing in FIG. 5A is a plan view. The lower left drawing in FIG. 5A is a side view. The lower right drawing in FIG. 5A is a cross-sectional view. This point also applies to FIGS. 5B to 5E, and FIGS. 6 to 9. The process of preparing the substrate 20 is a process of preparing the substrate 20 to be used in the wiring substrate 10. Any substrate can be used as the substrate 20. A substrate 20 on which a solder resist layer has been formed is preferably used. The substrate 20 is preferably a build-up substrate or a subtractive substrate. In the substrate 20, an opening for exposing the conductor layer 26 is formed in order to form the electrical connection member 50.

### Forming Lower Cladding

FIG. 5B illustrates a process of forming the lower cladding 41. The process of forming the lower cladding 41 is a process of forming the lower cladding 41 on the substrate 20. The lower cladding 41 is formed on the substrate 20 by spin-coating application. The lower cladding 41 can be formed using a resin film. The lower cladding 41 can have any desired thickness. The thickness of the lower cladding 41 is preferably 5 to 100 μm, and more preferably 10 to 50 μm.

### Forming Core

FIG. 5C illustrates a process of forming the core 42. The process of forming the core 42 is a process of forming the core 42 on the lower cladding 41. The core 42 is formed on the lower cladding 41 by spin-coating application, followed by exposure and development to achieve a predetermined shape. The core 42 can be formed using a resin film. An exposed portion of the core 42 is rectangular. The core 42 may have a tapered shape (a tapered shape that is reduced in width toward the left side in the drawing) (see the dotted line). The core 42 can be any desired thickness. The thickness of the core 42 is preferably 1 to 20 μm, and more preferably 3 to 10 μm.

The core 42 may be compatible with single-mode or multi-mode. The core 42 can have any desired width (a lateral length of the core 42 as viewed in the side view). The width of the core 42 is preferably 1 to 40 μm, and more preferably 3 to 20 μm. A height of the core is preferably 1 to 40 μm, and more preferably 3 to 20 μm. The shape of the core 42 (the shape of the core 42 as viewed in the side view) may be square, rectangular, circular, elliptical, or any other shape.

The number of cores 42 can be any desired value. The number of cores 42 is preferably 2 to 64. The number of cores 42 is preferably an even number. In the illustrated example, the number of cores 42 is four; however, it may be three or fewer, or five or more. A cladding may be formed on side surfaces of the core 42. In this case, the cladding can be formed by irradiating the resin used for the core 42 with radiation to change the refractive index of the resin. The core 42 can be formed by photolithography, photobleaching, or core cutting.

### Forming Upper Cladding

FIG. 5D illustrates a process of forming the upper cladding 43. The process of forming the upper cladding 43 is a process of forming the upper cladding 43 on the core 42. The upper cladding 43 is formed on the substrate 20 by spin-coating application. The upper cladding 43 can be formed using a resin film. The upper cladding 43 can have any desired thickness. The thickness of the upper cladding 43 is preferably 5 to 100 μm, and more preferably 10 to 50 μm. The lower cladding 41, the core 42, and the upper cladding 43 constitute an optical waveguide 40. In this case, an optical waveguide 40 may be formed with the core 42 exposed at one end, or with the core 42 exposed at the other end, or with the core 42 exposed at both ends.

### Mounting Optical Element

FIG. 5E illustrates a process of mounting an optical element 60. The mounting process of an optical element 60 is a process of mounting the optical element 60 on the substrate 20. In the mounting process of the optical element 60, the exposed portion of the core 42 and the terminal 61 of the optical element 60 are optically coupled. One end of the optical element 60 (the lower surface on the right side in FIG. 5E) is optically coupled with the core 42. The other end of the optical element 60 (the lower surface on the left side in FIG. 5E) is electrically connected to the electrical connection member 50.

The optical element 60 can be mounted after the electrical connection member 50 has been formed on the substrate 20 on which the optical waveguide 40 is formed. The electrical connection member 50 may be formed on the substrate 20 on which the optical waveguide 40 is formed. The optical waveguide 40 may be formed on the substrate 20 on which the electrical connection member 50 has been formed. The electrical connection member 50 is a metal body and may be a solder bump or a conductive post. The solder bump may be formed, for example, using tin-based solder, gold-based solder, or the like. The conductive post may be formed using a metal such as nickel or copper. When necessary, the electrical connection member 50 may have a structure of two or more layers, for example, a two-layer structure including a conductor post and tin-based solder, gold-based solder, or the like on the conductor post.

A transparent resin may be formed between the optical element 60 and the optical waveguide 40. An underfill may be formed between the optical element 60 and the electrical connection member 50. At the other end of the optical waveguide 40 (the right-side end portion in FIG. 5E), an external connection member 70 (see FIG. 1A) can be positioned. Further, the chip 80 can be positioned when necessary. The wiring substrate 10 and the like can be manufactured by such processes.

The wiring substrate 10 can adopt, for example, the following four connection forms. However, the connection forms are not limited to these. These connection forms can be applied not only to the wiring substrate 10 but also to the wiring substrate (10A), the wiring substrate (10B), the wiring substrate (10C), the wiring substrate (10D), the wiring substrate (10E), the wiring substrate (10F), the wiring substrate (10G), the wiring substrate (10H), the wiring substrate (10I), the wiring substrate (10J), the wiring substrate (10K), and the like.

### First Connection Form

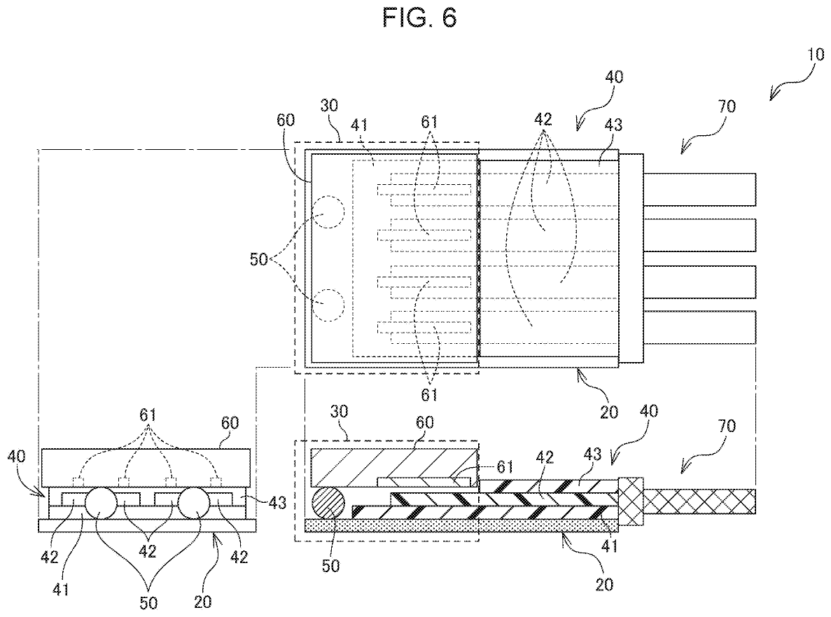

FIG. 6 illustrates a wiring substrate 10 of a first connection form. The wiring substrate 10 of the first connection form is a form in which the optical element 60 is connected to one end of the optical waveguide 40, and the external connection member 70 is connected to the other end of the optical waveguide 40. The optical element region 30 is formed at one end of the optical waveguide 40, and the external connection member 70 is positioned at the other end of the optical waveguide 40. In the optical waveguide 40, the core 42 is exposed at one end and is not exposed at the other end. Instead of the external connection member 70, an optical waveguide may be formed. The right end (the other end) of the optical waveguide 40 is flush with the right end of the substrate 20.

### Second Connection Form

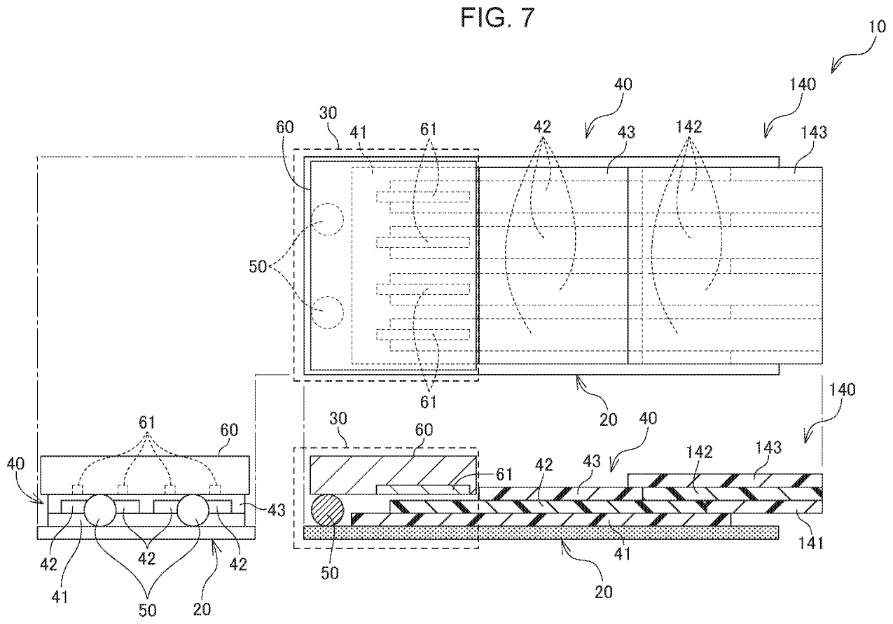

FIG. 7 illustrates a wiring substrate 10 of a second connection form. The wiring substrate 10 of the second connection form is a form in which the optical element 60 is connected to one end of the optical waveguide 40 and an optical waveguide 140 is connected to the other end of the optical waveguide 40. The optical element region 30 is formed at one end of the optical waveguide 40, and the optical waveguide 140 with a core 142 exposed is formed at the other end of the optical waveguide 40. In this case, the terminal 61 of the optical element 60 and the core 42 at the one end of the optical waveguide 40 are optically coupled. Further, the core 42 at the other end of the optical waveguide 40 and the core 142 of the optical waveguide 140 are optically coupled. In the wiring substrate 10 of the second connection form, in the optical waveguide 40 on the left side, the core 42 is exposed at both ends. This point also applies to a third connection form and a fourth connection form.

### Third Connection Form

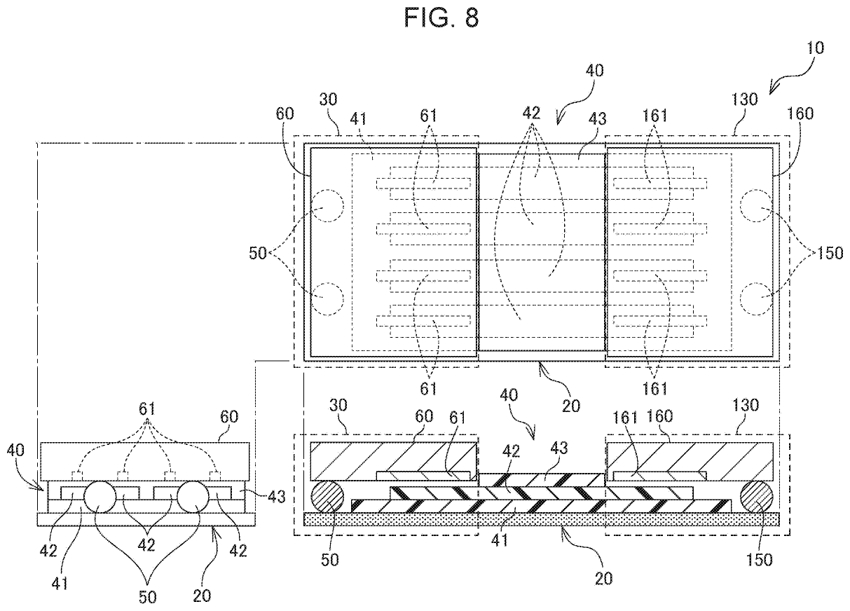

FIG. 8 illustrates a wiring substrate 10 of the third connection form. The wiring substrate 10 of the third connection form is a form in which the optical element 60 is connected to one end of the optical waveguide 40, and an optical element 160 is connected to the other end of the optical waveguide 40. The optical element region 30 is formed at one end of the optical waveguide 40, and an optical element region 130 different from the optical element region 30 is formed at the other end of the optical waveguide 40. One or multiple optical elements 160 can be disposed in the other optical element region 130. In this case, the terminal 61 of the optical element 60 and the core 42 at one end of the optical waveguide 40 are optically coupled. Further, a terminal 161 of the other optical element 160 and the core 42 at the other end of the optical waveguide 40 are optically coupled. The conductor layer of the substrate 20 and the optical element 60 are electrically connected by the electrical connection member 50. The conductor layer of the substrate 20 and the optical element 160 are electrically connected by electrical connection members 150.

### Fourth Connection Form

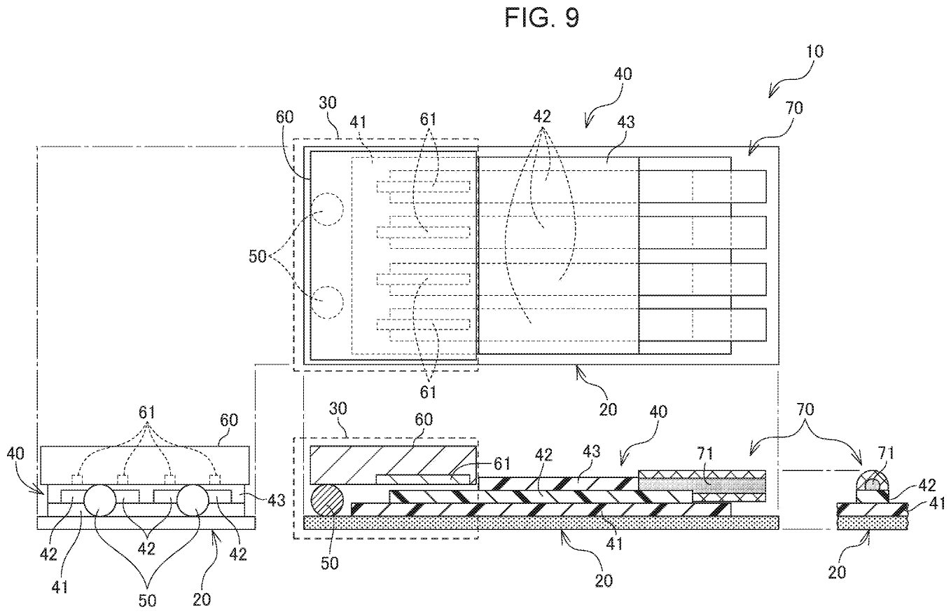

FIG. 9 illustrates a wiring substrate 10 of the fourth connection form. The lower right drawing in FIG. 9 is a cross-sectional view of a connection portion between the optical waveguide 40 and the external connection member 70. The wiring substrate 10 of the fourth connection form is a form in which the optical element 60 is connected to one end of the optical waveguide 40, and the external connection member 70 is connected to the other end of the optical waveguide 40. The optical element region 30 is formed at one end of the optical waveguide 40, and the external connection member 70 (for example, an optical fiber) with an exposed core 71 is formed at the other end of the optical waveguide 40. In this case, the terminal 61 of the optical element 60 and the core 42 of the optical waveguide 40 are optically coupled. Further, the core 42 of the optical waveguide 40 and the core 71 of the external connection member 70 are optically coupled. The external connection member 70 may have the same connection form with respect to the wiring substrate 10, or may have a different connection form with respect to the wiring substrate 10. For example, multiple connection portions of the external connection member 70 may have the same connection form, or may have different connection forms. Further, when multiple optical waveguides are formed on one side of the wiring substrate 10, the external connection member 70 may have the same connection form with respect to the multiple optical waveguides, or may have different connection forms with respect to the multiple optical waveguides. That is, the connection form of the external connection member 70 can be freely changed. Further, the connection forms of the multiple connection portions included in the external connection member 70 can be freely changed.

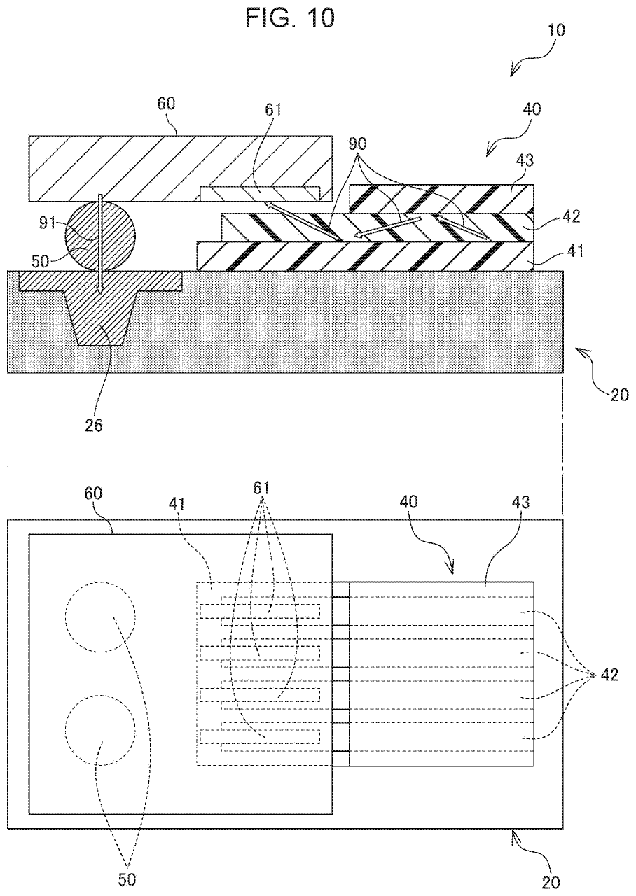

FIG. 10 illustrates an adiabatic coupling. The upper drawing in FIG. 10 is a cross-sectional view of the wiring substrate 10. The lower drawing in FIG. 10 is a plan view of the wiring substrate 10. The adiabatic coupling optically couples the exposed core 42 of the optical waveguide 40 and the terminal 61 of the optical element 60. An optical signal 90 passes through the core 42 of the optical waveguide 40 and is output to the terminal 61 of the optical element 60. The optical element 60 converts the optical signal 90 into an electrical signal 91. The electrical signal 91 is output and transmitted to the conductor layer 26 via the electrical connection member 50. The terminal 61 is made of a semiconductor material or an inorganic material. The terminal 61 forms, for example, an optical waveguide made of silicon. The core 42 is made of an organic material or an inorganic material. The core 42 forms, for example, an optical waveguide made of a thermosetting resin or an ultraviolet-curable resin.

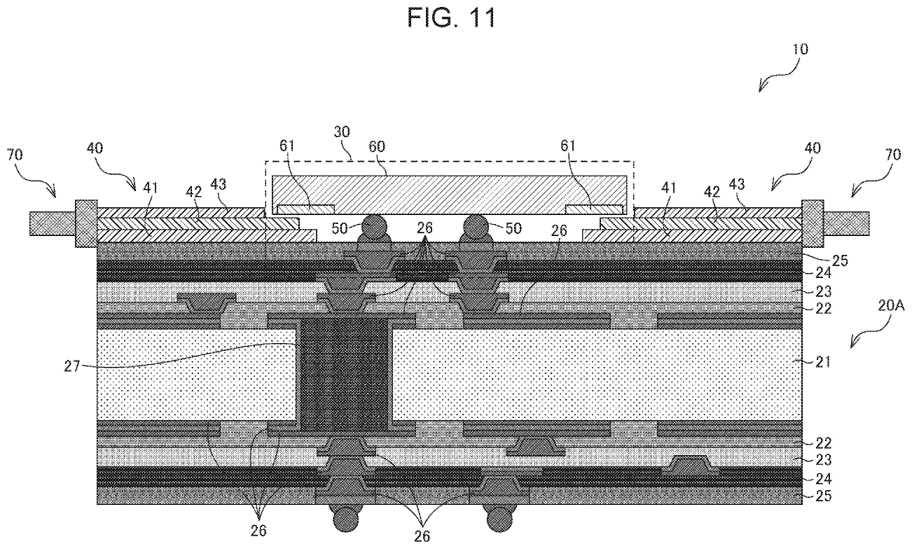

FIG. 11 is a cross-sectional view for describing a build-up substrate. As the substrate 20 illustrated in FIG. 1A, a build-up substrate (20A) illustrated in FIG. 11 can be used. The build-up substrate 20A includes a core substrate 21, a first insulating layer 22, a second insulating layer 23, a third insulating layer 24, a solder resist layer 25, a conductor layer 26, and a through hole 27. The first insulating layer 22, the second insulating layer 23, and the third insulating layer 24 are build-up layers formed on both sides of the core substrate 21. The number of insulating layers may be two or less, or may be four or more.

The build-up substrate (20A) can have any desired size. The size of the build-up substrate (20A) is preferably 200 mm or less in length×200 mm or less in width, and more preferably 120 mm or less in length×120 mm or less in width.

On the build-up substrate (20A), multiple optical waveguides 40 and optical elements 60 are positioned. The optical element 60 and the build-up substrate (20A) are connected by the electrical connection member 50. At one end of the optical waveguide 40 (the inner end portion in FIG. 11), the optical element region 30 can be formed. At the other end of the optical waveguide 40 (the outer end portion in FIG. 11), an external connection member 70 (for example, an optical fiber, an optical element, or the like) or another optical waveguide can be formed.

Manufacturing processes of the wiring substrate 10 (the build-up substrate (20A)) are as follows. The wiring substrate 10 is not limited to this content. The following description illustrates an example of the manufacturing processes of the wiring substrate 10. The manufacturing processes of the wiring substrate 10 are not limited to these details.

### Forming Core Substrate

The process of forming the core substrate 21 is a process of forming the core substrate 21 to be used in the build-up substrate (20A). In the process of forming the core substrate 21, a through hole 27 penetrating from front to back is formed in the core substrate 21, such as a double-sided copper-clad laminate, by drilling or irradiation with laser light. A conductor is formed on an inner wall of the through hole 27 by plating, and the conductor layer 26 is formed using a semi-additive method or a tenting method. A cavity of the through hole 27 can be filled with resin. The cavity of the through hole 27 may be filled with a conductor. The conductor layer 26 is formed on both sides of the core substrate 21. Unevenness between the conductor layer 26 and the core substrate 21 can be filled with resin to be flattened.

### Forming Insulating Layers

The process of forming the insulating layers is a process of forming the insulating layers (the first insulating layer 22, the second insulating layer 23, and the third insulating layer 24) using an insulating resin. In the process of forming the insulating layers, an uneven layer is formed on the conductor layer 26 of the core substrate 21 using a solution or by plating. The uneven layer improves adhesion between the conductor layer 26 and the insulating resin. As the insulating resin, a thermosetting resin or an ultraviolet-curable resin can be used. An insulating layer is formed by curing the insulating resin. The insulating resin can be formed by thermocompression bonding with a film or by application with a resin composition. As an example, an insulating layer is formed by laminating and thermocompression bonding an insulating resin such as a film-like epoxy resin. In the insulating layer, a through hole penetrating the insulating layer is formed by irradiation with laser light such as CO2 laser.

After forming the through hole, a conductor layer 26 is formed on the insulating layer using semi-additive method or the like. As a result, a via conductor is formed in the through hole of the insulating layer. The insulating layer is subjected to a roughening treatment using a strong oxidizing agent (such as chromic acid or permanganate). The roughening treatment roughens a resin surface to facilitate adhesion of chemical copper. After the roughening treatment, a catalyst is applied to the entire substrate, and an electroless plating film is formed on the insulating layer. The electroless plating film contains copper, nickel, or the like. A thickness of the electroless plating film is not particularly limited, but is preferably 0.1 to 5 μm. A dry film is formed on the insulating layer on which the electroless plating has been formed. A conductor circuit pattern is formed in the dry film by exposure. The exposed dry film is developed with a chemical such as an alkali to partially remove the film. As a result, a dry film formation portion and a dry film non-formation portion can be formed on the substrate. An electroplating film is formed in the dry film non-formation portion. The electroplating film contains copper, nickel, or the like. A thickness of the electroplating film is not particularly limited, but is preferably 3 to 20 μm. After that, the dry film is peeled off, and a substrate with the conductor layer 26 formed thereon can be obtained by chemical etching. Furthermore, by forming an insulating layer on the substrate on which the conductor layer 26 has been formed, a substrate on which multiple conductor layers are formed can be obtained. The number of insulating layers is not limited. As an example, three layers formed of the first insulating layer 22, the second insulating layer 23, and the third insulating layer 24 are formed. As a result, a substrate on which multiple conductor layers are formed is obtained. Then, by bonding two such substrates together vertically, a build-up substrate having a structure of three insulating layers-two core substrates-three insulating layers is obtained.

### Forming Solder Resist Layer

The process of forming the solder resist layer 25 is a process of forming the solder resist layer 25 on the third insulating layer 24. In the process of forming the solder resist layer 25, the solder resist layer 25 is formed by application or spraying of a photosensitive epoxy resin. In the solder resist layer 25, an opening for exposing a portion of the conductor layer 26 is formed by exposure and development.

### Forming Electrical Connection Member

The process of forming the electrical connection member 50 is a process of forming the electrical connection member 50 on the solder resist layer 25. In the process of forming the electrical connection member 50, the electrical connection member 50 is formed by mounting a conductive ball such as solder and performing reflow processing or the like. The build-up substrate (20A) is completed by the above processes.

### Forming Optical Waveguide

The process of forming the optical waveguide 40 is a process of forming the optical waveguide 40 on the build-up substrate (20A). In the process of forming the optical waveguide 40, multiple optical waveguides 40 are formed on the solder resist layer 25. Optical elements 60 are positioned between the multiple optical waveguides 40. The wiring substrate 10 is completed by the above processes.

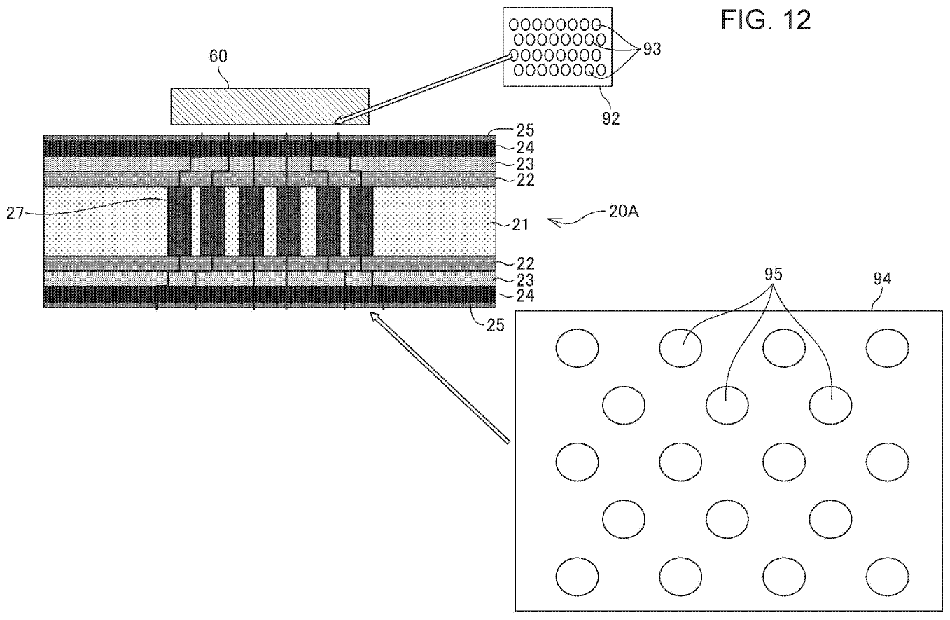

FIG. 12 is a cross-sectional view illustrating a structure of the build-up substrate (20A). As the buildup substrate (20A), a substrate having a fan-out structure can be used. The fan-out structure is a structure in which wirings spread outward with respect to an optical element 60 (chip). On a back surface 92 of the optical element, a large number of circular external terminals 93 are formed. On a back surface 94 of the lower solder resist layer 25, a large number of circular external terminals 95 are formed. A size of each external terminal 95 is larger than a size of each external terminal 93. The number of external terminals 95 is less than the number of external terminals 93.

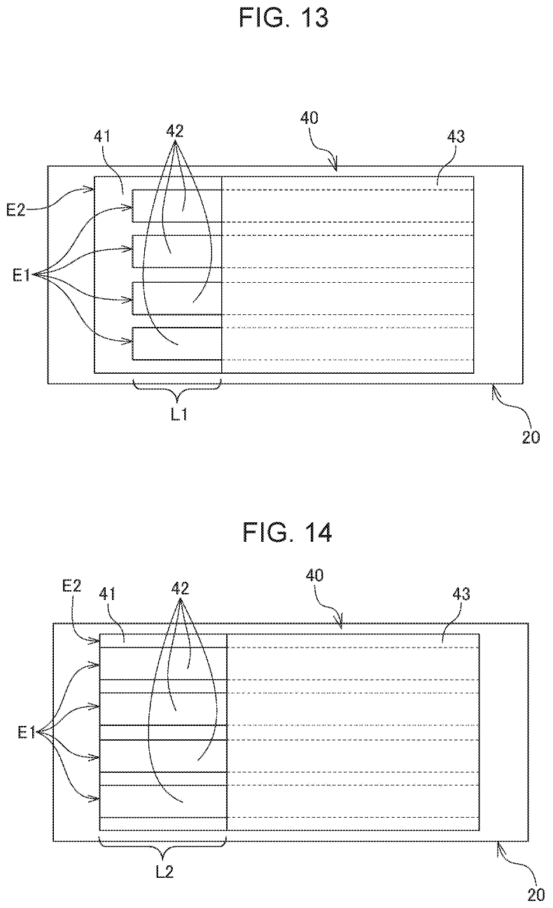

FIG. 13 is a plan view illustrating an optical waveguide 40 of a first example. In the optical waveguide 40 of the first example, an end portion (E1) of the core 42 is formed on an inner side of an end portion (E2) of the lower cladding 41. An exposed length (L1) of the core 42 can be any desired length. The exposed length (L1) of the core 42 is preferably 10 mm or less, more preferably 5 mm or less, and even more preferably 3 mm or less. The exposed length (L1) of the core 42 is a distance from an end portion (left end) of the upper cladding 43 of the optical waveguide 40, through the exposed core 42, to an end portion (left end) of the core 42.

FIG. 14 is a plan view illustrating an optical waveguide 40 of a second example. In the optical waveguide 40 of the second example, the end portion (E1) of the core 42 is formed at a position aligned with the end portion (E2) of the lower cladding 41. An exposed length (L2) of the core 42 can be any desired length. The exposed length (L2) of the core 42 may be the same as the exposed length (L1) of the core 42 in FIG. 13, or may be longer than the exposed length (L1) of the core 42.

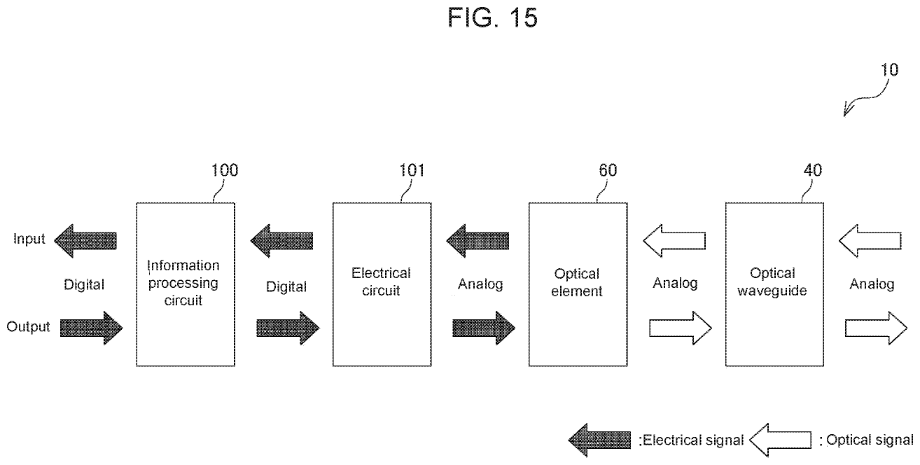

FIG. 15 illustrates roles of the components in the wiring substrate 10 and the like. The wiring substrate 10 and the like preferably include at least one of each of the components described below. The wiring substrate 10 and the like include an information processing circuit 100, an electrical circuit 101 (EIC: Electrical IC), an optical element 60, and an optical waveguide 40. The information processing circuit 100 performs information processing (computation). The information processing circuit 100 outputs a computation result as a digital signal to other components such as other information processing circuits. The electrical circuit 101 converts a digital waveform signal into an analog signal. The electrical circuit 101 converts an analog signal output from the optical element into a digital signal. The optical element 60 converts an optical signal into an analog electrical signal. The optical element 60 converts an analog electrical signal into an optical signal. The functions of the electrical circuit 101 may be included in the optical element 60. An optical element 60 that includes the functions of the electrical circuit 101 can convert an optical signal into an analog electrical signal and further convert an analog electrical signal into a digital signal. The chips (80, 81) in FIGS. 4A and 4B correspond to the electrical circuit 101 or the information processing circuit 100. The optical waveguide 40 transmits an optical signal to another optical element or the like. The optical waveguide 40 performs a role similar to that of copper wiring in electrical signals. The optical signal is in analog form.

The flow on the input side is as follows. An analog optical signal is input to the optical waveguide 40. The optical waveguide 40 outputs the analog optical signal. The analog optical signal is input to the optical element 60. The optical element 60 outputs an analog electrical signal. The analog electrical signal is input to the electrical circuit 101. The electrical circuit 101 outputs a digital electrical signal. The digital electrical signal is input to the information processing circuit 100. The information processing circuit 100 outputs a digital electrical signal.

The flow on the output side is as follows. A digital electrical signal is input to the information processing circuit 100. The information processing circuit 100 outputs a digital electrical signal. The digital electrical signal is input to the electrical circuit 101. The electrical circuit 101 outputs an analog electrical signal. The analog electrical signal is input to the optical element 60. The optical element 60 outputs an analog optical signal. The analog optical signal is input to the optical waveguide 40. The optical waveguide 40 outputs the analog optical signal.

Since the core 42 of the optical waveguide 40 is exposed, the height of the portion where the core 42 is exposed can be reduced. As a result, the height of the electrical connection member 50 can be reduced, and the wiring substrate 10 and the like having excellent electrical connectivity and optical coupling can be provided. The shorter the distance between the optical waveguide 40 and the optical element 60, the more connection failures can be reduced. Further, since multiple optical waveguides 40 are provided, the optical waveguides 40 can be used for various applications, and the wiring substrate 10 and the like with high expandability can be provided. Furthermore, since the core 42 of the optical waveguide 40 is exposed and multiple optical waveguides 40 are provided, a wiring substrate 10 having a novel structure can be provided.

Since one or multiple optical elements 60 are positioned in the optical element region 30, the number of optical elements 60 to be positioned can be flexibly changed.

Since the multiple optical waveguides 40 are formed in different directions (see FIGS. 1B, 2, and 3), applications of the optical waveguides 40 can be increased compared to a system in which the optical waveguides 40 are formed in one direction.

Since the core 42 at the other end is not exposed (see FIG. 6), loss of optical signals can be suppressed.

Since the core 42 at the other end is exposed (see FIGS. 7, 8, and 9), the height of the portion where the core 42 is exposed can be reduced at the other end as well.

Since the external connection member 70 (for example, an optical fiber) is positioned at the other end of the optical waveguide 40 (see FIG. 6), applications of the wiring substrate 10 and the like can be increased by utilizing the external connection member 70.

Since the optical waveguide 140 is formed at the other end of the optical waveguide 40 (see FIG. 7), applications of the wiring substrate 10 and the like can be increased by utilizing the optical waveguide 140.

Since another optical element region 30 is formed at the other end of the optical waveguide 40 (see FIG. 8), applications of the wiring substrate 10 and the like can be increased by utilizing the other optical element region 30.

Since the external connection member 70 (for example, an optical fiber) with the exposed core 71 is positioned at the other end of the optical waveguide 40 (see FIG. 9), applications of the wiring substrate 10 and the like can be increased by utilizing the external connection member 70 with the exposed core 71.

Since the chip 80 for connecting multiple optical elements 60 is provided (see FIGS. 4A and 4B), multiple optical elements 60 can be operated in cooperation with each other.

Since the end portion (E1) of the core 42 is formed on an inner side of the end portion (E2) of the lower cladding 41 (see FIG. 13), damage to the core 42 at the end portion (E1) of the core 42 can be avoided.

Since the end portion (E1) of the core 42 is formed at a position aligned with the end portion (E2) of the lower cladding 41 (see FIG. 14), the exposed portion of the core 42 can be lengthened.

Since the substrate 20 can be the build-up substrate (20A) (see FIG. 11), the performance of the wiring substrate 10 and the like can be improved.

Multiple optical waveguides 40 with the core 42 exposed are formed on the substrate 20. Therefore, the wiring substrate 10 and the like can be obtained in which, in the bonding between the optical element 60 and the optical waveguide 40 and in the connection between the optical element 60 and the substrate 20, the distance between the optical element 60 and the core 42 and the distance between the optical element 60 and the conductor layer 26 of the substrate 20 become shorter, and optical coupling of optical signals or electrical connection of electrical signals is efficiently performed. Further, even when the optical signals or electrical signals become large in capacity, these signals can still be efficiently communicated. Moreover, in the wiring substrate 10 and the like, by reducing the height of the electrical connection member 50, the electrical connection member 50 becomes less prone to damage, and therefore connection reliability can be improved.

### Modified Embodiments

The present invention is not limited to the above-described embodiment and can be implemented with various modifications. When the optical waveguides 40 are formed in two directions, they may be formed in an L-shape, such as on the left side and the upper side, the left side and the lower side, the right side and the upper side, the right side and the lower side, or the like. Although the optical waveguides 40 have been described using examples in which they are formed in two to four directions, they may be formed in five or more directions. The wiring substrate does not necessarily need to include the chip 80 or the chip 81.

Japanese Patent Application Laid-Open Publication No. 2003-215371 describes an optical module in which an optical waveguide provided with an inclined mirror is formed on a substrate. Japanese Patent Application Laid-Open Publication No. 2003-215371 also describes an optical module having a surface-type optical element that is mounted on an upper surface of an optical waveguide and in which a substrate-side pad and a surface-type optical element-side pad are connected by a solder bump.

A wiring substrate according to an embodiment of the present invention includes: a substrate having a conductor layer; an optical element region; multiple optical waveguides each having a lower cladding, a core, and an upper cladding; and an electrical connection member. The optical element region and the multiple optical waveguides are formed on the substrate. The electrical connection member is provided in the optical element region and electrically connects the conductor layer and the optical element region. The core of each of the multiple optical waveguides that optically couples with the optical element region is exposed.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a substrate having an optical element region and comprising a conductor layer formed in the optical element region;
a plurality of optical waveguides formed on the substrate such that each of the optical waveguides includes a lower cladding, a core and an upper cladding; and
an electrical connection member formed in the optical element region of the substrate and configured to electrically connect the conductor layer and an optical element in the optical element region of the substrate,
wherein the plurality of optical waveguides is formed on the substrate such that the core of each of the optical waveguides is exposed in the optical element region of the substrate and optically couples with the optical element.

2. The wiring substrate according to claim 1, further comprising:
the optical element positioned in the optical element region of the substrate.

3. The wiring substrate according to claim 1, wherein the optical waveguides are formed in different directions with respect to the optical element region in a center of the optical waveguides.

4. The wiring substrate according to claim 1, wherein the plurality of optical waveguides is formed such that each of the optical waveguides has two ends and that the core of each of the optical waveguides is exposed at one end of the two ends and not exposed at the other end of the two ends.

5. The wiring substrate according to claim 1, wherein the plurality of optical waveguides is formed such that each of the optical waveguides has two ends and that the core of each of the optical waveguides is exposed at the two ends.

6. The wiring substrate according to claim 1, wherein the plurality of optical waveguides is formed on the substate such that each of the optical waveguides has two ends, that one end of the two ends in each of the optical waveguides is formed in the optical element region of the substrate and that the other end of the two ends in each of the optical waveguides is configured to connect to an external connection member.

7. The wiring substrate according to claim 1, further comprising:
a plurality of second optical waveguides formed on the substrate such that each of the second optical waveguides includes a lower cladding, a core and an upper cladding,
wherein the plurality of optical waveguides is formed on the substate such that each of the optical waveguides has two ends, that one end of the two ends in each of the optical waveguides is formed in the optical element region of the substrate and that the core of each of the second optical waveguides is exposed and positioned at the other end of the two ends in each of the optical waveguides.

8. The wiring substrate according to claim 1, wherein the substrate has a second optical element region, and the plurality of optical waveguides is formed on the substate such that each of the optical waveguides has two ends, that one end of the two ends in each of the optical waveguides is formed in the optical element region of the substrate and that the other end of the two ends in each of the optical waveguides is formed in the second optical element region of the substrate.

9. The wiring substrate according to claim 1, wherein the plurality of optical waveguides is formed on the substate such that each of the optical waveguides has two ends, that one end of the two ends in each of the optical waveguides is formed in the optical element region of the substrate and that the other end of the two ends in each of the optical waveguides is configured to connect to an external connection member having an exposed core.

10. The wiring substrate of claim 1, further comprising:
a chip positioned on the substrate; and
a plurality of optical elements including the optical element and positioned in the optical element region of the substrate such that the chip is electrically connected to the optical elements.

11. The wiring substrate according to claim 1, wherein the plurality of optical waveguides is formed on the substate such that an end portion of the core is formed on an inner side of an end portion of the lower cladding.

12. The wiring substrate according to claim 1, wherein the plurality of optical waveguides is formed on the substate such that an end portion of the core is formed at a position aligned with an end portion of the lower cladding.

13. The wiring substrate according to claim 1, wherein the substrate is a buildup substrate comprising a core substrate, a first buildup layer formed on a first side of the core substrate, and a second buildup layer formed on a second side of the core substrate on an opposite side with respect to the first side.

14. The wiring substrate according to claim 2, wherein the optical waveguides are formed in different directions with respect to the optical element region in a center of the optical waveguides.

15. The wiring substrate according to claim 2, wherein the plurality of optical waveguides is formed such that each of the optical waveguides has two ends and that the core of each of the optical waveguides is exposed at one end of the two ends and not exposed at the other end of the two ends.

16. The wiring substrate according to claim 2, wherein the plurality of optical waveguides is formed such that each of the optical waveguides has two ends and that the core of each of the optical waveguides is exposed at the two ends.

17. The wiring substrate according to claim 2, wherein the plurality of optical waveguides is formed on the substate such that each of the optical waveguides has two ends, that one end of the two ends in each of the optical waveguides is formed in the optical element region of the substrate and that the other end of the two ends in each of the optical waveguides is configured to connect to an external connection member.

18. The wiring substrate according to claim 2, wherein the substrate has a second optical element region, and the plurality of optical waveguides is formed on the substate such that each of the optical waveguides has two ends, that one end of the two ends in each of the optical waveguides is formed in the optical element region of the substrate and that the other end of the two ends in each of the optical waveguides is formed in the second optical element region of the substrate.

19. The wiring substrate according to claim 2, wherein the plurality of optical waveguides is formed on the substate such that an end portion of the core is formed on an inner side of an end portion of the lower cladding.

20. The wiring substrate according to claim 2, wherein the plurality of optical waveguides is formed on the substate such that an end portion of the core is formed at a position aligned with an end portion of the lower cladding.
